(19) United States
(12) Patent Application Publication
(10) Pub. No.: US 2025/0185461 A1
(43) Pub. Date: Jun. 5, 2025

(54) DISPLAY DEVICE AND MOBILE ELECTRONIC DEVICE INCLUDING SAME

(71) Applicant: Samsung Display Co., LTD., Yongin-si (KR)

(72) Inventors: Ji Hye LEE, Yongin-si (KR); Kyung Bae KIM, Yongin-si (KR); Jin Seon KWAK, Yongin-si (KR)

(21) Appl. No.: 18/882,449

(22) Filed: Sep. 11, 2024

(30) Foreign Application Priority Data
Dec. 1, 2023 (KR) 10-2023-0172312

(51) Int. Cl. H10K 59/121

(52) U.S. Cl. CPC H10K 59/1213

(57) ABSTRACT

A display device includes a pixel driver circuit including a plurality of pixel transistors; a scan driver including a first transistor group and a second transistor group; and a display panel including a semiconductor substrate, a complementary metal oxide semiconductor (CMOS) layer on the semiconductor substrate, and an emission material layer on the CMOS layer, wherein the CMOS layer includes a first well area doped with first-type impurities and a second well area doped with second-type impurities, the first and second well areas being in a display area of the display panel, and wherein the plurality of pixel transistors and the first transistor group are in the first well area, and the second transistor group is in the second well area.

### CROSS-REFERENCE TO RELATED APPLICATION

The present application claims priority to and the benefit of Korean Patent Application No. 10-2023-0172312, filed on Dec. 1, 2023, in the Korean Intellectual Property Office, the entire disclosure of which is incorporated herein by reference.

### BACKGROUND

### 1. Field of the Disclosure

Aspects of the present disclosure relate to a display device and a mobile electronic device including the same.

### 2. Description of the Related Art

Currently, wearable devices are being developed that are in the form of glasses or helmets. These devices are capable of forming a focal point at a location close to the user's eyes. For example, a wearable device may be a head mounted display (HMD) device or an AR glass. Such a wearable device provides a user with an augmented reality (hereinafter referred to as an “AR”) screen or a virtual reality (hereinafter referred to as a “VR”) screen.

A wearable device such as a HMD device and AR glasses require display specifications of at least 2,000 PPI (pixels per inch) to allow users to use it for a long time without dizziness. To this end, organic light-emitting diode on silicon (OLEDoS) technology is emerging, which enables a high-resolution small organic light-emitting element display device. The OLEDOS is a technology for depositing organic light-emitting diodes (OLED) on a semiconductor wafer substrate on which complementary metal oxide semiconductor (CMOS) is disposed.

The above information disclosed in this Background section is only for enhancement of understanding of the background of the invention and therefore it may contain information that does not form the prior art.

### SUMMARY

Aspects of the present disclosure are directed to a display device that can increase a size of the display screen by reducing a non-display area, and a mobile electronic device including the same.

According to some embodiments of the present disclosure, there is provided a display device including: a pixel driver circuit including a plurality of pixel transistors; a scan driver including a first transistor group and a second transistor group; and a display panel including a semiconductor substrate, a complementary metal oxide semiconductor (CMOS) layer on the semiconductor substrate, and an emission material layer on the CMOS layer, wherein the CMOS layer includes a first well area doped with first-type impurities and a second well area doped with second-type impurities, the first and second well areas being in a display area of the display panel, and wherein the plurality of pixel transistors and the first transistor group are in the first well area, and the second transistor group is in the second well area.

In some embodiments, the plurality of pixel transistors includes p-type MOSFETS.

In some embodiments, the first transistor group includes p-type MOSFETs, and the second transistor group includes n-type MOSFETs.

In some embodiments, the first-type impurities are n-type impurities, and the second-type impurities are p-type impurities.

In some embodiments, the plurality of pixel transistors includes n-type MOSFETS.

In some embodiments, the first transistor group includes n-type MOSFETs, and the second transistor group includes p-type MOSFETs.

In some embodiments, the first-type impurities are p-type impurities, and the second-type impurities are n-type impurities.

In some embodiments, the first well area and the second well area are adjacent to each other to form one twin-well area, and a plurality of twin well areas including the twin well area is arranged in a matrix pattern in the display area.

In some embodiments, the first well area and the second well area correspond to four sub-pixels of the display panel that are arranged in a 2×2 matrix, and the first well area surrounds the second well area.

In some embodiments, the first well area includes a pair of first well areas, the pair of first well areas and the second well area correspond to four sub-pixels of the display panel that are arranged in a 2×2 matrix, and the second well area is located between the pair of first well areas.

According to some embodiments of the present disclosure, there is provided a mobile electronic device including: a display panel including a semiconductor substrate, a complementary metal oxide semiconductor (CMOS) layer on the semiconductor substrate, and an emission material layer on the CMOS layer, wherein the CMOS layer includes a first well area doped with first-type impurities and a second well area doped with second-type impurities, the first and second well areas being in a display area of the display panel, and wherein a plurality of pixel transistors of a pixel driver circuit and a first transistor group of a scan driver are in the first well area, and a second transistor group of the scan driver is in the second well area.

In some embodiments, the plurality of pixel transistors includes p-type MOSFETs.

In some embodiments, the first transistor group includes p-type MOSFETS, and the second transistor group includes n-type MOSFETs.

In some embodiments, the first-type impurities are n-type impurities, and the second-type impurities are p-type impurities.

In some embodiments, the plurality of pixel transistors includes n-type MOSFETS.

In some embodiments, the first transistor group includes n-type MOSFETs, and the second transistor group includes p-type MOSFETs.

In some embodiments, the first-type impurities are p-type impurities, and the second-type impurities are n-type impurities.

In some embodiments, the first well area and the second well area are adjacent to each other to form one twin-well area, and a plurality of twin well areas including the twin well area is arranged in a matrix pattern in the display area.

In some embodiments, the first well area and the second well area correspond to four sub-pixels of the display panel that are arranged in a 2×2 matrix, and the first well area surrounds the second well area.

In some embodiments, the first well area includes a pair of first well areas, the pair of first well areas and the second well area correspond to four sub-pixels that are arranged in a 2×2 matrix, and the second well area is located between the pair of first well areas.

In a display device and a mobile electronic device including the same according to embodiments, the size of the display screen can be expanded by reducing the non-display area.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a perspective view of a head-mounted display device according to some embodiments of the present disclosure.

FIG. 2 is an exploded perspective view of an the head-mounted display device of FIG. 1, according to some embodiments of the present disclosure.

FIG. 3 is a perspective view of a head-mounted display device according to some embodiments of the present disclosure.

FIG. 4 is an exploded perspective view showing a display device according to some embodiments of the present disclosure.

FIG. 5 is a view showing a layout of a display panel according to a comparative example.

FIG. 6 is a view showing a layout of the display panel of FIG. 4, according to some embodiments of the present disclosure.

FIG. 7 is a block diagram showing a display device according to some embodiments of the present disclosure.

FIG. 8 is an equivalent circuit diagram of a first sub-pixel according to some embodiments of the present disclosure.

FIG. 9 is an equivalent circuit diagram of a scan driver according to some embodiments of the present disclosure.

FIG. 10 is a cross-sectional view showing an example of a part of a display panel according to some embodiments of the present disclosure.

FIG. 11 is a cross-sectional view showing a layout of a first sub-pixel according to some embodiments of the present disclosure.

FIG. 12 is a view showing a layout of a pixel group according to some embodiments of the present disclosure.

FIG. 13 is an equivalent circuit diagram of a first sub-pixel according to some embodiments of the present disclosure.

FIG. 14 is a view showing a layout of a pixel group according to some embodiments of the present disclosure.

### DETAILED DESCRIPTION OF THE EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

Features of each of various embodiments of the present disclosure may be partially or entirely combined with each other and may technically variously interwork with each other, and respective embodiments may be implemented independently of each other or may be implemented together in association with each other.

Hereinafter, some specific embodiments will be described with reference to the accompanying drawings.

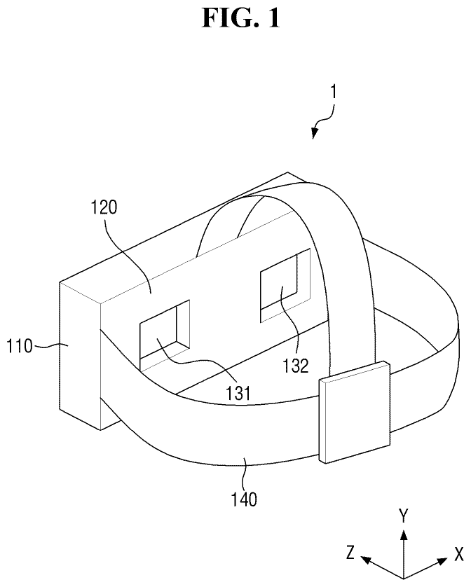

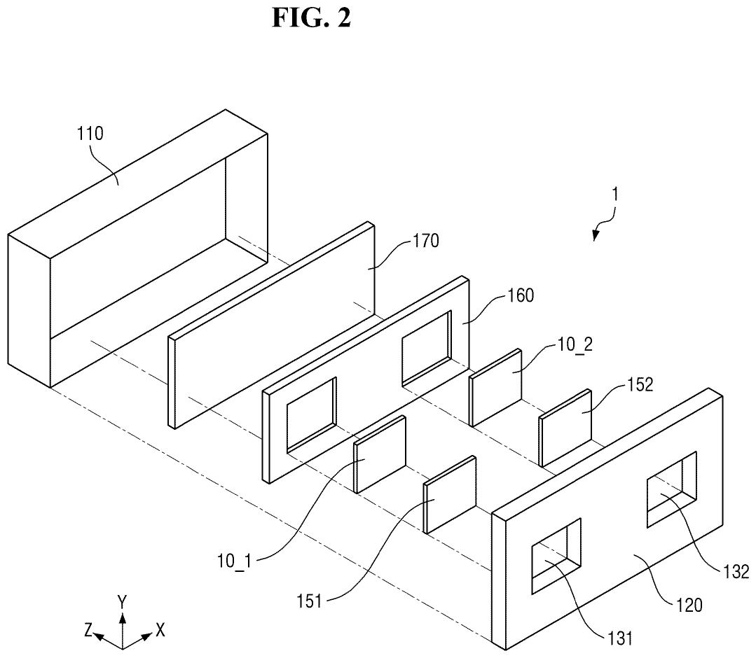

FIG. 1 is a perspective view of a head-mounted display device according to some embodiments of the present disclosure. FIG. 2 is an exploded perspective view of the head-mounted display device of FIG. 1, according to some embodiments of the present disclosure.

Referring to FIGS. 1 and 2, a head-mounted display device 1 according to some embodiments includes a first display device 10_1, a second display device 10_2, a display device housing 110, and a housing cover 120, a first eyepiece 131, a second eyepiece 132, a head strap band 140, a middle frame 160, a first optical member 151, a second optical member 152, a control circuit board 170, and a connector.

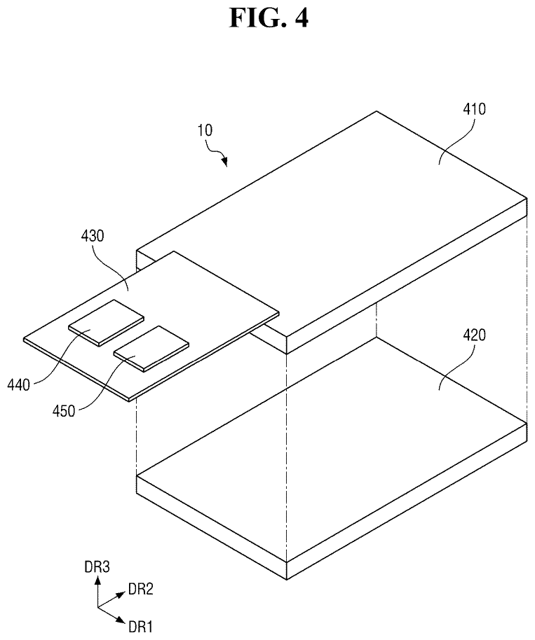

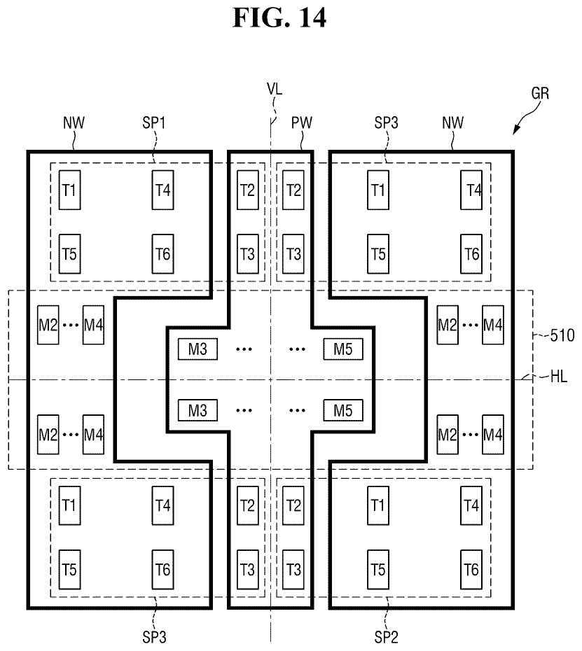

The first display device 10_1 provides images to a user's left eye, and the second display device 10_2 provides images to the user's right eye. Each of the first display device 10_1 and the second display device 10_2 is identical or substantially identical to the display device 10 described with reference to FIGS. 4 and 14. Therefore, for the descriptions of the first display device 10_1 and the second display device 10_2 one may refer to the descriptions with reference to FIGS. 4 to 14.

The first optical member 151 may be disposed between the first display device 10_1 and the first eyepiece 131. The second optical member 152 may be disposed between the second display device 10_2 and the second eyepiece 132. Each of the first optical member 151 and the second optical member 152 may include at least one convex lens.

The middle frame 160 may be disposed between the first display device 10_1 and the control circuit board 170, and may be disposed between the second display device 10_2 and the control circuit board 170. The middle frame 160 serves to support and fix the first display device 10_1, the second display device 10_2, and the control circuit board 170.

The control circuit board 170 may be disposed between the middle frame 160 and the display device housing 110. The control circuit board 170 may be connected to the first display device 10_1 and the second display device 10_2 through a connector. The control circuit board 170 may convert an image input from the outside into digital video data (DATA) and may transmit the digital video data (DATA) to the first display device 10_1 and the second display device 10_2 through the connector.

The control circuit board 170 may transmit digital video data (DATA) associated with a left eye image, which is configured (e.g., optimized) for the user's left eye, to the first display device 10_1, and may transmit digital video data (DATA) associated with a right eye image, which is configured (e.g., optimized) for the user's right eye, to the second display device 10_2. In some examples, the control circuit board 170 may transmit the same digital video data (DATA) to the first display device 10_1 and the second display device 10_2.

The display device housing 110 accommodates the first display device 10_1, the second display device 10_2, the middle frame 160, the first optical member 151, the second optical member 152, the control circuit board 170, and the connector. The housing cover 120 is disposed to cover the open face of the housing 110. The housing cover 120 may include the first eyepiece 131 where the user's left eye is placed, and the second eyepiece 132 where the user's right eye is placed. Although the first eyepiece 131 and the second eyepiece 132 are separately disposed in the example shown in FIGS. 1 and 2, the embodiments of the present disclosure are not limited thereto. The first eyepiece 131 and the second eyepiece 132 may be combined into a single element.

The first eyepiece 131 may be aligned with the first display device 10_1 and the first optical member 151, and the second eyepiece 132 may be aligned with the second display device 10_2 and the second optical member 152. Therefore, a user may see virtual images on the first display device 10_1 magnified by the first optical member 151 through the first eyepiece 131, and virtual images on the second display device 10_2 magnified by the second optical member 152 through the second eyepiece 132. Herein, the term “virtual images” refers to artificial images generated and displayed by the display device 1.

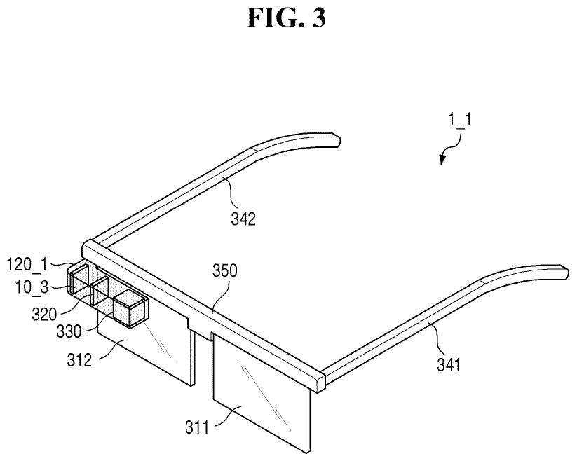

The head strap band 140 fixes the housing 110 to the user's head so that the first eyepiece 131 and the second eyepiece 132 of the housing cover 120 remain in line with the user's left and right eyes, respectively. By implementing a light and small display device housing 120, the head-mounted display device 1 may include an eyeglasses frame as shown in FIG. 3 instead of a head strap band 140.

In addition, the head-mounted display device 1 may further include a battery for supplying power, an external memory slot for inserting an external memory, and an external connection port, and a wireless communication module for receiving an image. The external connection port may be a USB (universe serial bus) terminal, a display port, or an HDMI (high-definition multimedia interface) terminal. The wireless communication module may be a 5G communication module, a 4G communication module, a Wi-Fi module, or a Bluetooth module.

FIG. 3 is a perspective view of a head-mounted display device according to some embodiments of the present disclosure.

Referring to FIG. 3, the head-mounted display device 1_1 according to some embodiments may be a glasses-type display device with a light and small display device housing 120_1. The head-mounted display device 1_1 according to some embodiments may include display devices 10_3, a left-eye lens 311, a right eye lens 312, a support frame 350, eyeglass temples 341 and 342, optical members 320, optical path conversion members 330, and display device housings 120_1.

The display device 10_3 shown in FIG. 3 is identical or substantially identical to the display device 10 described with reference to FIGS. 4 to 14. Therefore, for the descriptions of the first display device 10_1 and the second display device 10_2 one may refer to the descriptions referring to FIGS. 4 and 14.

The display device housings 120_1 may include the display devices 10_3, the optical members 320, and the optical path conversion members 330. The images displayed on the display device 10_3 may be enlarged by the optical member 320, and the optical paths of the images are converted by the optical path conversion member 330 to be provided to the user's right eye through the right eye lens 312. As a result, the user can see, with the right eye, augmented reality images that combine virtual images generated by and displayed on the display device 10_3 and real world images viewed through the right eye lens 312.

Although the display device housing 120_1 is disposed at the right end of the support frame 350 in the example shown in FIG. 3, the embodiments of the present disclosure are not limited thereto. For example, the display device housing 120_1 may be disposed at the left end of the support frame 350. In such cases, images displayed on the display device 10_3 may be provided to the user's left eye. In some examples, the display device housing 120_1 may be disposed at both the left and right ends of the support frame 350. In such cases, the user can watch images displayed on the display device 10_3 through both the left and right eyes.

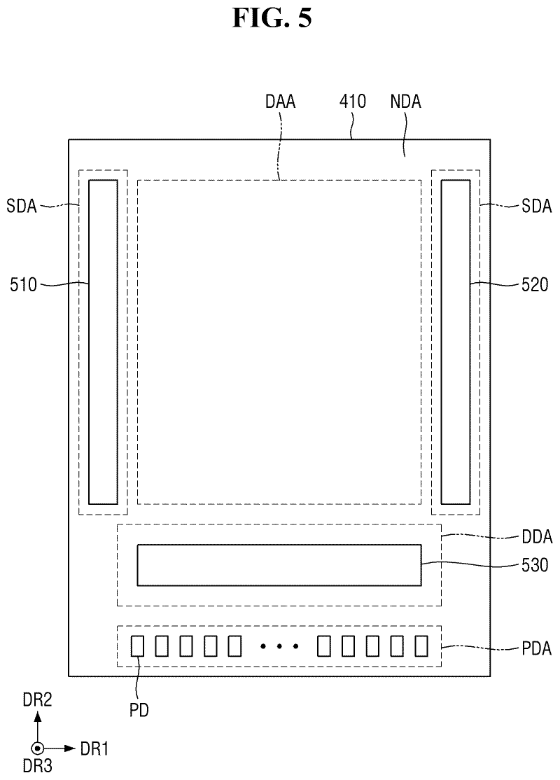

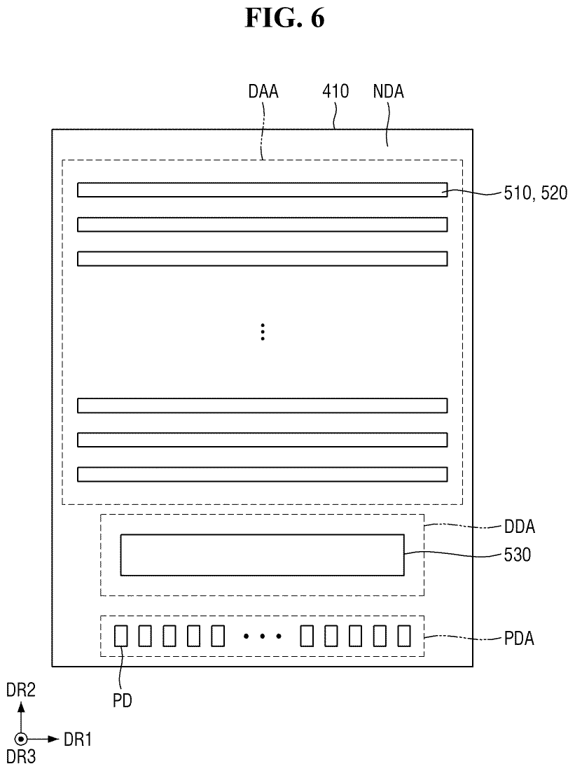

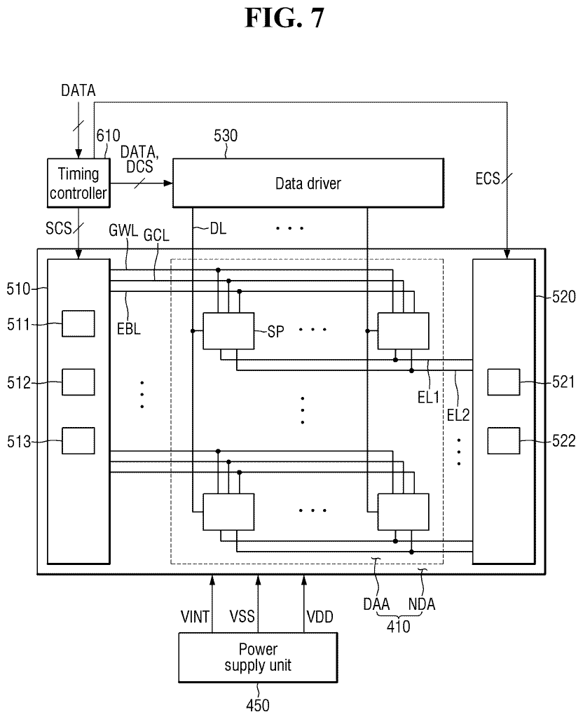

FIG. 4 is an exploded, perspective view showing a display device according to some embodiments of the present disclosure. FIG. 5 is a view showing a layout of a display panel according to comparative example. FIG. 6 is a view showing a layout of the display panel of FIG. 4, according to some embodiments of the present disclosure. FIG. 7 is a block diagram showing a display device according to some embodiments of the present disclosure.

Referring to FIGS. 4 and 5, the display device 10 may display moving images and still images. The display device 10 according to some embodiments may be employed by portable electronic devices such as a mobile phone, a smart phone, a tablet PC, a mobile communications terminal, an electronic notebook, an electronic book, a portable multimedia player (PMP), a navigation device and a ultra mobile PC (UMPC). For example, the display device 10 may be used as a display unit of a television, a laptop computer, a monitor, an electronic billboard, or an Internet of Things (IoT) device. In some examples, the display device 10 may be applied to a smart watch, a watch phone, or a head-mounted display (HMD) for implementing virtual reality and augmented reality.

According to some embodiments, the display device 10 includes a display panel 410, a heat dissipation layer 420, a circuit board 430, and a driver circuit 440.

The display panel 410 may have a shape similarly to a rectangular shape when viewed from the top. For example, the display panel 410 may have a shape similar to a rectangle having shorter sides in the first direction DR1 and longer sides in the second direction DR2 intersecting the first direction DR1 when viewed from the top. In the display panel 410, the corners where the shorter sides in the first direction DR1 meet the longer sides in the second direction DR2 may be rounded with a set or predetermined curvature or may form a right angle. The shape of the display panel 410 when viewed from the top is not limited to a rectangular shape, but may be formed in a shape similar to other polygonal shapes, a circular shape, or an elliptical shape. The shape of the display device 10 may follow the shape of the display panel 410 when viewed from the top, but the embodiments of the present disclosure are not limited thereto.

The display panel 410 may include a display area DAA where images are displayed, and a non-display area NDA where no image is displayed.

The display area DAA includes a plurality of sub-pixels SP, a plurality of scan lines SL, a plurality of emission control lines EL, and a plurality of data lines DL.

The sub-pixels SP include light-emitting elements LE that emit light. The sub-pixels SP may be arranged in a matrix in the first direction DR1 and the second direction DR2. The scan lines SL and the emission control lines EL may extend in the first direction DR1 and may be arranged in the second direction DR2. The data lines DL may extend in the second direction DR2 and may be arranged in the first direction DR1.

The plurality of scan lines SL includes a plurality of write scan lines GWL, a plurality of control scan lines GCL, and a plurality of bias scan lines EBL. The plurality of emission control lines EL includes a plurality of first emission control lines EL1 and a plurality of second emission control lines EL2.

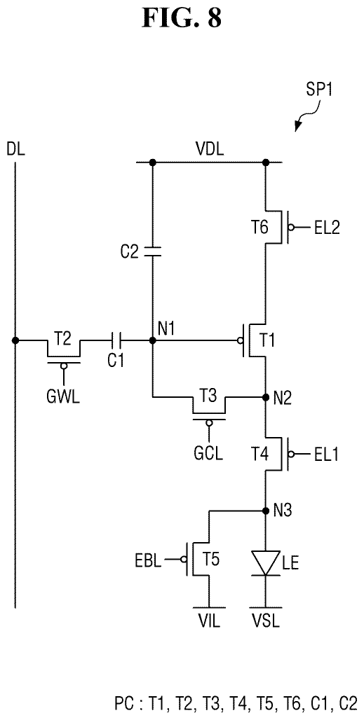

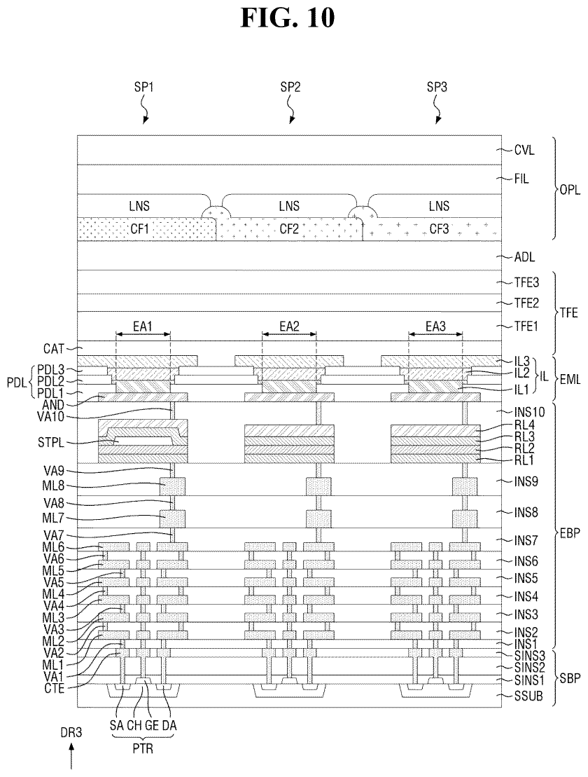

As will be described later with reference to FIG. 10, a plurality of sub-pixels SP may include a first sub-pixel SP1, a second sub-pixel SP2, and a third sub-pixel SP3. Each of the plurality of sub-pixels SP1, SP2, and SP3 includes a plurality of pixel transistors T1, T2, T3, T4, T5, and T6 as shown in FIG. 8. A plurality of pixel transistors T1, T2, T3, T4, T5, and T6 (see, e.g., FIG. 8) may be formed via a semiconductor process and may be disposed on a semiconductor substrate SSUB (see, e.g., FIG. 10). For example, a plurality of pixel transistors T1, T2, T3, T4, T5, and T6 (see, e.g., FIG. 8) may be formed of complementary metal oxide semiconductor (CMOS).

Each of the plurality of sub-pixels SP (e.g., SP1, SP2, or SP3) may be connected to one of the write scan lines GWL, one of the control scan lines GCL, one of the bias scan lines EBL, one of the first emission control lines EL1, one of the second emission control lines EL2, and one of the data lines DL. Each of the sub-pixels SP1, SP2, and SP3 may receive the data voltage from the data line DL according to the write scan signal from the write scan line GWL, and may allow the light-emitting elements to emit light according to the data voltage.

According to the comparative example shown in FIG. 5, the non-display area NDA of the display panel 410 includes a scan driving area SDA, a data driving area DDA, and a pad area PDA.

In the scan driving area SDA, a scan driver 510 and an emission driver 520 are disposed.

The scan driver 510 includes a plurality of scan transistors, and the emission driver 520 includes a plurality of light-emitting transistors. A plurality of scan transistors and a plurality of light-emitting transistors are formed via a semiconductor process and may be formed on the semiconductor substrate SSUB (see, e.g., FIG. 10). For example, a plurality of scan transistors and a plurality of light-emitting transistors may be formed of CMOS.

Referring to FIG. 7, the scan driver 510 may include a write scan signal output unit 511, a control scan signal output unit 512, and a bias scan signal output unit 513. Each of the write scan signal output unit 511, the control scan signal output unit 512, and the bias scan signal output unit 513 may receive a scan timing control signal SCS from a timing control circuit (also referred to as a timing controller) 610. The write scan signal output unit 511 may generate write scan signals according to the scan timing control signal SCS from the timing control circuit 610 and sequentially output them to the write scan lines GWL. The control scan signal output unit 512 may generate control scan signals according to the scan timing control signal SCS and sequentially output them to the control scan lines GCL. The bias scan signal output unit 513 may generate bias scan signals according to the scan timing control signal SCS and sequentially output them to the bias scan lines EBL.

Referring to FIG. 7, the emission driver 520 includes a first emission control driver 521 and a second emission control driver 522. Each of the first emission control driver 521 and the second emission control driver 522 may receive an emission timing control signal ECS from the timing control circuit 610. The first emission control driver 521 may generate first emission control signals according to the emission timing control signal ECS and sequentially output them to the first emission control lines EL1. The second emission control driver 522 may generate second emission control signals according to the emission timing control signal ECS and sequentially output them to the second emission control lines EL2.

In the data driving area DDA, the data driver 530 may be disposed. The data driver 530 may include a plurality of data transistors, and the plurality of data transistors may be formed via a semiconductor process and may be formed on the semiconductor substrate SSUB (see, e.g., FIG. 10). For example, the plurality of data transistors may be formed of CMOS.

The data driver 530 may receive digital video data DATA and a data timing control signal DCS from the timing control circuit 610. The data driver 530 converts the digital video data DATA into analog data voltages according to the data timing control signal DCS and outputs them to the data lines DL. In doing so, the sub-pixels SP1, SP2, and SP3 are selected by the write scan signal of the scan driver 510, and data voltages may be applied to the selected sub-pixels SP1, SP2, and SP3.

The pad area PDA includes a plurality of pads PD arranged in the first direction DR1. Each of the plurality of pads PD may be exposed without being covered by a cover layer and a polarizer.

The heat dissipation layer 420 may overlap with the display panel 410 in the third direction DR3, which is the thickness direction of the display panel 410. The heat dissipation layer 420 may be disposed on one surface of the display panel 410, for example, on the rear surface. The heat dissipation layer 420 serves to discharge heat generated in the display panel 410. The heat dissipation layer 420 may include a metal layer, such as graphite, silver (Ag), copper (Cu), and aluminum (Al), and/or the like, which has a high thermal conductivity.

The circuit board 430 may be electrically connected to a plurality of pads PD in a pad area PDA of the display panel 410 using a conductive adhesive member such as an anisotropic conductive film. The circuit board 430 may be a flexible printed circuit board made of a flexible material, or a flexible film. Although the circuit board 430 is unfolded in FIG. 4, the circuit board 430 may be bent. When it is bent, one end of the circuit board 430 may be disposed on the rear surface of the display panel 410. The one end of the circuit board 430 may be opposite to the opposite end of the circuit board 430, which is connected to (e.g., adhered to) the pads PD in the pad area PDA of the display panel 410 using a conductive adhesive member.

The timing control circuit 610 may receive digital video data and timing signals from the outside (e.g., from outside of the display device 1). The timing control circuit 610 may generate a scan timing control signal SCS, an emission timing control signal ECS, and a data timing control signal DCS for controlling the display panel 410 in response to the timing signals. The timing control circuit 610 may output the scan timing control signal SCS to the scan driver 510 and output the emission timing control signal ECS to the emission driver 520. The timing control circuit 610 may output the digital video data and the data timing control signal DCS to the data driver 530.

A power supply circuit 450 may generate a plurality of panel driving voltages in response to a supply voltage from the outside. For example, the power supply circuit 450 may generate a first supply voltage VSS, a second supply voltage VDD, and a third supply voltage VINT to apply them to the display panel 410.

Each of the timing control circuit 610 and the power supply circuit 450 may be implemented as an integrated circuit (IC) and attached to a surface of the circuit board 430. The scan timing control signal SCS, the emission timing control signal ECS, the digital video data DATA, and the data timing control signal DCS from the timing control circuit 610 may be supplied to the display panel 410 through the circuit board 430. The first supply voltage VSS, the second supply voltage VDD, and the third supply voltage VINT of the power supply circuit 450 may be supplied to the display panel 410 through the circuit board 430.

It should be noted that the non-display area NDA of the display panel 410 according to some embodiments shown in FIG. 6 may not include the scan driving area SDA, unlike the comparative example shown in FIG. 5. For example, the scan driver 510 and the emission driver 520 of the scan drive area SDA, which were described above with reference to FIG. 5, may be disposed in the display area DAA. A plurality of scan transistors and a plurality of light-emitting transistors may be formed of CMOS, and they may be disposed adjacent to a plurality of pixel transistors T1, T2, T3, T4, T5, and T6 (see, e.g., FIG. 8).

The display panel 410 according to the embodiments shown in FIG. 6 can reduce the non-display area NDA compared to comparative example shown in FIG. 5. Accordingly, the display panel 410 according to some embodiments can reduce the bezel area (or dead space area) where no image is displayed. For example, while the scan driver 510 and the emission driver 520 are disposed in the scan driving area SDA outside the display area DAA according to the comparative example shown in FIG. 5, the scan driving area SDA is eliminated according to the embodiments shown in FIG. 6, and thus the non-display area NDA can be reduced.

FIG. 8 is an equivalent circuit diagram of a first sub-pixel according to some exemplary embodiments of the present disclosure.

Referring to FIG. 8, a first sub-pixel SP1 may be connected to a write scan line GWL, a control scan line GCL, a bias scan line EBL, a first emission control line EL1, a second emission control line EL2, and a data line DL. In addition, the first sub-pixel SP1 may be connected to a first supply voltage line VSL where the first supply voltage VSS equal to a low-level voltage is applied, a second supply voltage line VDL where the second supply voltage VDD equal to a high-level voltage is applied, and a third supply voltage line VIL where the third supply voltage VINT equal to an initialization voltage is applied. In other words, the first supply voltage line VSL may be a low-level voltage line, the second supply voltage line VDL may be a high-level voltage line, and the third supply voltage line VIL may be an initialization voltage line. The first supply voltage VSS may be lower than the third supply voltage VINT. The second supply voltage VDD may be higher than the third supply voltage VINT.

The first sub-pixel SP1 includes a light-emitting element LE, and a pixel driving circuit PC connected to the light-emitting element LE. The pixel driving circuit PC includes a plurality of transistors T1, T2, T3, T4, T5, and T6, a first capacitor C1, and a second capacitor C2.

The light-emitting element LE emits light according to a driving current Ids flowing in a channel of the first transistor T1. The amount of the light emitted from the light-emitting element LE may be proportional to the driving current Ids. The light-emitting element LE may be disposed between the fourth transistor T4 and the first supply voltage line VSL. The first electrode of the light-emitting element LE may be connected to a drain electrode of the fourth transistor T4, and the second electrode thereof may be connected to the first supply voltage line VSL. The first electrode of the light-emitting element LE may be an anode electrode (or a pixel electrode), and the second electrode of the light-emitting element LE may be a cathode electrode (or a common electrode). The light-emitting element LE may be an organic light-emitting diode including a first electrode, a second electrode, and an organic light-emitting layer disposed between the first electrode and the second electrode. It should be understood, however, that the present disclosure is not limited thereto. For example, the light-emitting element LE may be an inorganic light-emitting element including a first electrode, a second electrode, and an inorganic semiconductor disposed between the first electrode and the second electrode. In such examples, the light-emitting element LE may be a micro light-emitting diode.

The first transistor T1 may be a driving transistor for controlling the source-drain current Ids (hereinafter referred to as “driving current”) flowing between the source electrode and the drain electrode according to the voltage applied to the gate electrode. The first transistor T1 includes a gate electrode connected to a first node N1, a source electrode connected to a drain electrode of the sixth transistor T6, and a drain electrode connected to a second node N2.

The second transistor T2 may be disposed between one electrode of the first capacitor C1 and the data line DL. The second transistor T2 is turned on (e.g., is activated) by a write scan signal from the write scan line GWL and connects the electrode of the first capacitor C1 to the data line DL. Accordingly, the data voltage of the data line DL may be applied to the electrode of the first capacitor C1. The second transistor ST2 includes a gate electrode connected to the write scan line GWL, a source electrode connected to the data line DL, and a drain electrode connected to the electrode of the first capacitor C1.

A third transistor T3 may be connected between the first node N1 and the second node N2. The third transistor T3 is turned on by the write control signal of the write control line GCL and connects the first node N1 to the second node N2. Accordingly, the gate electrode and source electrode of the first transistor T1 are connected with each other, and thus the first transistor T1 can act like a diode when the write control signal is applied. The third transistor T3 includes a gate electrode connected to the write control line GCL, a source electrode connected to the second node N2, and a drain electrode connected to the first node N1.

The fourth transistor T4 may be connected between the second node N2 and the third node N3. The fourth transistor ST4 is turned on by a first emission control signal of the first emission control line EL1 and connects the second node N2 to the third node N3. Accordingly, the driving current of the first transistor T1 may be supplied to the light-emitting element LE. The fourth transistor T4 includes a gate electrode connected to the first emission control line EL1, a source electrode connected to the second node N2, and a drain electrode connected to the third node N3.

The fifth transistor T5 may be disposed between the third node N3 and the third supply voltage line VIL. The fifth transistor T5 is turned on by a bias scan signal of the bias scan line EBL and connects the third node N3 to the third supply voltage line VIL. Accordingly, the third supply voltage VINT of the third supply voltage line VIL may be applied to the first electrode of the light-emitting element LE. The fifth transistor T5 includes a gate electrode connected to the bias scan line EBL, a source electrode connected to the third node N3, and a drain electrode connected to the third supply voltage line VIL.

The sixth transistor T6 may be disposed between the source electrode of the first transistor T1 and the second supply voltage line VDL. The sixth transistor T6 is turned on by the second emission control signal of the second emission control line EL2 and connects the source electrode of the first transistor T1 to the second supply voltage line VDL. Accordingly, the second driving voltage VDD of the second supply voltage line VDL may be applied to the source electrode of the first transistor T1. The sixth transistor T6 includes a gate electrode connected to the second emission control line EL2, a source electrode connected to the second supply voltage line VDL, and a drain electrode connected to the source electrode of the first transistor T1.

The first capacitor C1 is formed between the first node N1 and the drain electrode of the second transistor T2. The first capacitor C1 includes a first electrode connected to the drain electrode of the second transistor T2, and a second electrode connected to the first node N1.

The second capacitor C2 is formed between the gate electrode of the driving transistor DT and the second supply voltage line VDL. The second capacitor C2 includes a first electrode connected to the gate electrode of the first transistor T1 and a second electrode connected to the second supply voltage line VDL.

The first node N1 is a contact point where the gate electrode of the first transistor T1, the drain electrode of the third transistor T3, the second electrode of the first capacitor C1 and the first electrode of the second capacitor C2 meet. The second node N2 is a contact point where the drain electrode of the first transistor T1, the source electrode of the third transistor T3 and the source electrode of the fourth transistor T4 meet. The third node N3 is a contact point where the drain electrode of the fourth transistor T4, the source electrode of the fifth transistor T5, and the first electrode of the light-emitting element LE meet.

Each of the first to sixth transistors T1, T2, T3, T4, T5, and T6 may be a metal-oxide-semiconductor field effect transistor (MOSFET). For example, each of the first to sixth transistors T1, T2, T3, T4, T5, and T6 may be, but is not limited to, a p-type MOSFET. For example, each of the first to sixth transistors T1, T2, T3, T4, T5, and T6 may be an n-type MOSFET. In some examples, some of the first to sixth transistors T1, T2, T3, T4, T5, and T6 may be p-type MOSFETs, and the remaining transistors may be n-type MOSFETs.

Although the first sub-pixel SP1 includes the six transistors T1, T2, T3, T4, T5, and T6 and the two capacitors C1 and C2 in the example shown in FIG. 8, it should be noted that the equivalent circuit diagram of the sub-pixel SP1 is not limited to that shown in FIG. 8. For example, the numbers of the transistors and the capacitors of the first sub-pixel SP1 are not limited to those shown in FIG. 8.

In addition, the equivalent circuit diagram of the second sub-pixel SP2 and the equivalent circuit diagram of the third sub-pixel SP3 may be identical or substantially identical to the equivalent circuit diagram of the first sub-pixel SP1 described above with reference to FIG. 8; and, therefore, the descriptions thereof may not repeated for the sake of brevity.

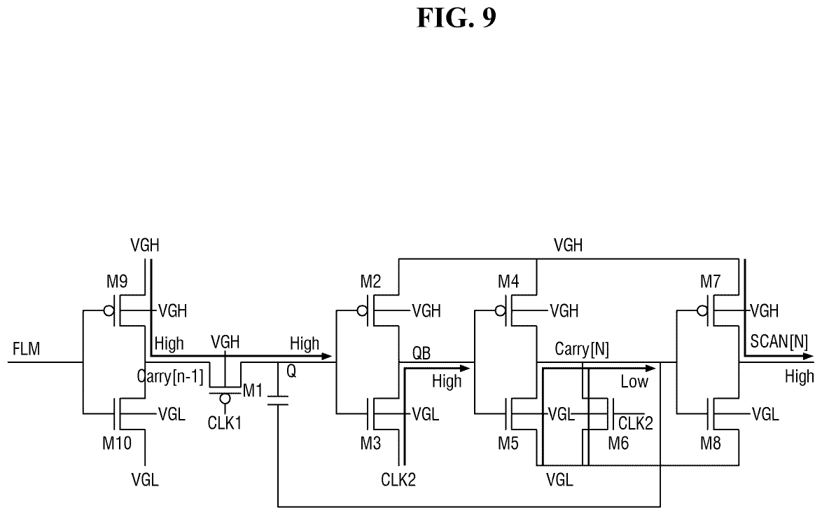

FIG. 9 is an equivalent circuit diagram of a scan driver 510 according to some embodiments of the present disclosure.

Referring to FIG. 9, the scan driver 510 outputs a scan signal in the form of pulses by outputting a high-level voltage or a low-level voltage depending on the potentials of a Q-node and a QB node. To this end, the scan driver 510 includes a plurality of scan transistors.

As shown in FIG. 9, the plurality of scan transistors may include, but is not limited to, first to tenth scan transistors M1, M2, M3, M4, M5, M6, M7, M8, M9, and M10.

The first scan transistor M1 receives a carry signal through the ninth scan transistor M9 or the tenth scan transistor M10, and charges the Q-node Q in response to a carry signal Carry [n−1]. In some examples, the first scan transistor M1 and the ninth scan transistor M9 may be p-type MOSFETs, while the tenth scan transistor M10 may be an n-type MOSFET.

The second scan transistor M2 and the third scan transistor M3 charge the QB-node QB according to the voltage level of the Q-node Q. The second scan transistor M2 may be a p-type MOSFET, and the third scan transistor M3 may be an n-type MOSFET. A clock signal CLK2 in the form of pulses may be input to the drain electrode of the third scan transistor M3.

The fourth to eighth scan transistors M4, M5, M6, M7, and M8 output a high-level voltage VGH at the output terminal of the scan driver 510 when the Q-node Q is charged to the high level, and output the low-level voltage VGL at the output terminal of the scan driver 510 when the QB-node QB is charged to the high level. The fourth scan transistor M4 and the seventh scan transistor M7 are p-type MOSFETs, and the fifth scan transistor M5, the sixth scan transistor M6 and the eighth scan transistor M8 may be n-type MOSFETs.

As described above, the scan driver 510 includes a plurality of scan transistors M1, M2, M3, M4, M5, M6, M7, M8, M9, and M10, and some of the plurality of scan transistors M1, M2, M3, M4, M5, M6, M7, M8, M9, and M10 may be n-type MOSFETs, while the others may be p-type MOSFETs. For example, the first scan transistor M1, the second scan transistor M2, the fourth scan transistor M4, the seventh scan transistor M7 and the ninth scan transistor M9 may be p-type MOSFETs, and these may be referred to as a first transistor group. For example, the third scan transistor M3, the fifth scan transistor M5, the sixth scan transistor M6, the eighth scan transistor M8 and the tenth scan transistor M10 may be n-type MOSFETs, and these may be referred to as a second transistor group. However, embodiments of the present disclosure are not limited thereto. For example, the transistors of the first transistor group may be n-type MOSFETs and the transistors of the second transistor group may be p-type MOSFETs (assuming the corresponding gate control signals are inverted).

According to some embodiments, some of the plurality of scan transistors M1, M2, M3, M4, M5, M6, M7, M8, M9, and M10 of the scan driver 510 may be disposed in a well area of the display area DAA where pixel transistors PTR are disposed. For example, a first well area NW doped with first-type impurities and a second well area PW doped with second-type impurities are located in a CMOS layer in the display area DAA of the display panel 100. A plurality of pixel transistors included in the pixel driver circuit and the first transistor group of the scan driver 510 are disposed in the first well area NW, and the second transistor group of the scan driver 510 is disposed in the second well area PW. The CMOS layer may refer to a semiconductor backplane SBP, which will be described later with reference to FIG. 10.

FIG. 10 is a cross-sectional view showing an example of a part of a display panel according to some embodiments of the present disclosure.

Referring to FIG. 10, the display panel 100 includes a semiconductor backplane SBP, an emission material backplane EBP, an emission material layer EML, an encapsulation layer TFE, an optical layer OPL, a cover layer CVL, and a polarizer.

The semiconductor backplane SBP includes a semiconductor substrate SSUB including a plurality of pixel transistors PTR, a plurality of semiconductor insulating films covering the plurality of pixel transistors PTR, and a plurality of contact terminals CTE that are electrically connected to the pixel transistors PTR. The plurality of pixel transistors PTR may be the first to sixth transistors T1, T2, T3, T4, T5, and T6 described with reference to FIG. 8.

The semiconductor substrate SSUB may be a silicon substrate, a germanium substrate, or a silicon-germanium substrate. The semiconductor substrate SSUB may be a substrate doped with first-type impurities. A plurality of well areas WA may be located in the upper surface of the semiconductor substrate SSUB. The plurality of well areas WA may include a region doped with a first type impurity and a region doped with a second type impurity. The second-type impurities may be different from the first-type impurities. For example, when the first-type impurities are p-type impurities, the second-type impurities may be n-type impurities. In some examples, when the first-type impurities are n-type impurities, the second-type impurities may be p-type impurities.

Each of the well areas WA includes a source region SA associated with a source electrode of a pixel transistor PTR, a drain region DA associated with a drain electrode thereof, and a channel region CH between the source region SA and the drain region DA.

Each of the source region SA and the drain region DA may be doped with the first-type impurities. The gate electrode GE of the pixel transistor PTR may overlap with the well area WA in the third direction DR3. The channel region CH may overlap with the gate electrode GE in the third direction DR3. The source area SA may be located on one side of the gate electrode GE, and the drain area SA may be located on the opposite side of the gate electrode GE.

Each of the plurality of well areas WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may have a lower impurity concentration than the source region SA. The second low-concentration impurity region LDD2 may have a lower impurity concentration than the drain region DA. The distance between the source region SA and the drain region DA may be increased by the first low-concentration impurity region LDD1 and the second low-concentration impurity region LDD2. Therefore, the length of the channel region CH of each of the pixel transistors PTR can be increased, and thus it is possible to prevent or substantially reduce punch-through and hot carrier phenomenon due to a short channel.

A first semiconductor insulating film SINS1 may be disposed on the semiconductor substrate SSUB. The first semiconductor insulating film SINS1 may be formed of, but is not limited to, a silicon carbon nitride (SiCN) or a silicon oxide (SiOx)-based inorganic film.

A second semiconductor insulating film SINS2 may be disposed on the first semiconductor insulating film SINS1. The second semiconductor insulating film SINS2 may be formed of a silicon oxide (SiOx)-based inorganic film, but the embodiments of the present disclosure are not limited thereto, and any suitable material may be used.

A plurality of contact terminals CTE may be disposed on the second semiconductor insulating film SINS2. Each of the plurality of contact terminals CTE may be connected to one of the gate electrode GE, the region SA, and the drain region DA of each of the pixel transistors PTR through a hole penetrating the first semiconductor insulating film SINS1 and the second semiconductor insulating film INS2. The contact terminals CTE may be made of copper (Cu), aluminum (Al), tungsten (W), molybdenum (Mo), chromium (Cr), gold (Au), titanium (Ti), nickel (Ni), neodymium (Nd), or an alloy thereof.

A third semiconductor insulating film SINS3 may be disposed on the side surface of each of the contact terminals CTE. The upper surface of each of the contact terminals CTE may not be covered by the third semiconductor insulating film SINS3 but may be exposed. The third semiconductor insulating film SINS3 may be formed of a silicon oxide (SiOx)-based inorganic film, but the embodiments of the present disclosure are not limited thereto.

The semiconductor substrate SSUB may be replaced with a glass substrate or a polymer resin substrate such as polyimide. In such examples, thin-film transistors may be disposed on a glass substrate or a polymer resin substrate. The glass substrate may be a rigid substrate that is not bent, while the polymer resin substrate may be a flexible substrate that can be bent or curved.

The emission material backplane EBP includes first to eighth metal layers ML1 to ML8, reflective metal layers RL1 to RL4, a plurality of vias VA1 to VA10, and a step layer STPL. In addition, the emission material backplane EBP includes a plurality of interlayer dielectric films INS1 to INS10 disposed between the first to sixth metal layers ML1 to ML6.

The first to eighth metal layers ML1 to ML8 serve to implement a circuit of a first sub-pixel SP1 shown in FIG. 8 by connecting a plurality of contact terminals CTE exposed from the semiconductor backplane SBP. That is to say, the first to sixth transistors T1, T2, T3, T4, T5, and T6 are only formed in the semiconductor backplane SBP, and the connection of the first to sixth transistors T1, T2, T3, T4, T5, and T6 and the first capacitor C1 and the second capacitor C2 are made through the first to eighth metal layers ML1 to ML8. In addition, the connection between the drain region corresponding to the drain electrode of the fourth transistor T4, the source region corresponding to the source electrode of the fifth transistor T5, and the first electrode of the light-emitting element LE is also made through the first to eighth metal layers ML1 to ML8.

The first interlayer insulating film INS1 may be disposed on the semiconductor backplane SBP. Each of the first vias VA1 may penetrate the first interlayer insulating film INS1 and may be connected to the contact terminal CTE exposed from the semiconductor backplane SBP. Each of the first metal layers ML1 may be disposed on the first interlayer insulating film INS1 and may be connected to the first via VA1.

The second interlayer insulating film INS2 may be disposed on the first interlayer insulating film INS1 and the first metal layers ML1. Each of the second vias VA2 may penetrate through the second interlayer insulating film INS2 to be connected to the exposed first metal layer ML1. Each of the second metal layers ML2 may be disposed on the second interlayer insulating film INS2 and may be connected to the second via VA2.

The third interlayer insulating film INS3 may be disposed on the second interlayer insulating film INS2 and the second metal layers ML2. Each of the third vias VA3 may penetrate through the third interlayer insulating film INS3 to be connected to the exposed second metal layer ML2. Each of the third metal layers ML3 may be disposed on the third interlayer insulating film INS3 and may be connected to the third via VA3.

The fourth interlayer insulating film INS4 may be disposed on the third interlayer insulating film INS3 and the third metal layers ML3. Each of the fourth vias VA2 may penetrate through the fourth interlayer insulating film INS4 to be connected to the exposed third metal layer ML3. Each of the fourth metal layers ML4 may be disposed on the fourth interlayer insulating film INS4 and may be connected to the fourth via VA4.

The fifth interlayer insulating film INS5 may be disposed on the fourth interlayer insulating film INS4 and the fourth metal layers ML4. Each of the fifth vias VA5 may penetrate through the fifth interlayer insulating film INS5 to be connected to the exposed fourth metal layer ML4. Each of the fifth metal layers ML5 may be disposed on the fifth interlayer insulating film INS5 and may be connected to the fifth via VA5.

The sixth interlayer insulating film INS6 may be disposed on the fifth interlayer insulating film INS5 and the fifth metal layers ML5. Each of the sixth vias VA6 may penetrate through the sixth interlayer insulating film INS6 to be connected to the exposed fifth metal layer ML5. Each of the sixth metal layers ML6 may be disposed on the sixth interlayer insulating film INS6 and may be connected to the sixth via VA6.

The seventh interlayer insulating film INS7 may be disposed on the sixth interlayer insulating film INS6 and the sixth metal layers ML6. Each of the seventh vias VA7 may penetrate through the seventh interlayer insulating film INS7 to be connected to the exposed sixth metal layer ML6. Each of the seventh metal layers ML7 may be disposed on the seventh interlayer insulating film INS7 and may be connected to the seventh via VA7.

The eighth interlayer insulating film INS8 may be disposed on the seventh interlayer insulating film INS7 and the seventh metal layers ML7. Each of the eighth vias VA8 may penetrate through the eighth interlayer insulating film INS8 to be connected to the exposed seventh metal layer ML7. Each of the eighth metal layers ML8 may be disposed on the eighth interlayer insulating film INS8 and may be connected to the eighth via VA8.

The first to eighth metal layers ML1 to ML8 and the first to eighth vias VA1 to VA8 may be made of the same or substantially the same material. The first to eighth metal layers ML1 to ML8 and the first to eighth vias VA1 to VA8 may be made of copper (Cu), aluminum (Al), tungsten (W), molybdenum (Mo), chromium (Cr), gold (Au), titanium (Ti), nickel (Ni), neodymium (Nd), or an alloy thereof. The first to eighth vias VA1 to VA8 may be made of the same or substantially the same material. The first to eighth interlayer dielectric films INS1 to ILD8 may be formed of a silicon oxide (SiOx)-based inorganic film or the like, but embodiments of the present specification are not limited thereto.

The ninth interlayer insulating film INS9 may be disposed on the eighth interlayer insulating film INS8 and the eighth metal layers ML8. The ninth interlayer insulating film INS9 may be formed of a silicon oxide (SiOx)-based inorganic film or the like, but the embodiments of the present disclosure are not limited thereto.

Each of the ninth vias VA9 may penetrate through the ninth interlayer insulating film INS9 to be connected to the exposed eighth metal layer ML8. The ninth vias VA9 may be made of copper (Cu), aluminum (Al), tungsten (W), molybdenum (Mo), chromium (Cr), gold (Au), titanium (Ti), nickel (Ni), neodymium (Nd), or an alloy thereof.

The first reflective electrodes RL1 may be disposed on the ninth interlayer insulating film INS9 and may be connected to the ninth via VA9. The first reflective electrodes RL1 may be made of copper (Cu), aluminum (Al), tungsten (W), molybdenum (Mo), chromium (Cr), gold (Au), titanium (Ti), nickel (Ni), neodymium (Nd), or an alloy thereof.

The second reflective electrodes RL2 may be disposed on the first reflective electrodes RL1. The second reflective electrodes RL2 may be made of copper (Cu), aluminum (Al), tungsten (W), molybdenum (Mo), chromium (Cr), gold (Au), titanium (Ti), nickel (Ni), neodymium (Nd), or an alloy thereof. For example, the second reflective electrodes RL2 may be titanium nitride (TiN).

In the first sub-pixel SP1, a step layer STPL may be disposed on the second reflective electrode RL2. No step layer STPL may be disposed in each of the second sub-pixel SP2 and the third sub-pixel SP3. The thickness of the step layer STPL may be determined based on the wavelength of the light of a first color and the distance from a first emissive layer EML1 to a fourth reflective electrode RL4 so that the light of the first color emitted from the first emissive layer EML1 of the first sub-pixel SP1 is advantageously reflected. The step layer STPL may be formed of, but is not limited to, a silicon carbon nitride (SiCN) or a silicon oxide (SiOx)-based inorganic film.

In the first sub-pixel SP1, the third reflective electrode RL3 may be disposed on the second reflective electrode RL2 and the step layer STPL. In the second sub-pixel SP2 and the third sub-pixel SP3, the third reflective electrode RL3 may be disposed on the second reflective electrode RL2. The third reflective electrodes RL3 may be made of copper (Cu), aluminum (Al), tungsten (W), molybdenum (Mo), chromium (Cr), gold (Au), titanium (Ti), nickel (Ni), neodymium (Nd), or an alloy thereof.

At least one of the first reflective electrode RL1, the second reflective electrode RL2, and the third reflective electrode RL3 may be eliminated.

The fourth reflective electrodes RL4 may be disposed on the third reflective electrodes RL3. The fourth reflective electrodes RL4 may reflect lights from the first to third intermediate layers EML1, EML2 and EML3. The fourth reflective electrodes RL4 may include a metal with high reflectivity to facilitate light reflection. The fourth reflective electrodes RL4 may be made up of, but is not limited to, aluminum (Al), a stack of aluminum and titanium (Ti/Al/Ti), a stack of aluminum and ITO (ITO/Al/ITO), silver (Ag), palladium (Pd), and an APC alloy, which is an alloy of copper (Cu), a stack of an APC alloy and ITO (ITO/APC/ITO), and/or the like.

The tenth interlayer insulating film INS10 may be disposed on the ninth interlayer insulating film INS9 and the fourth reflective electrodes RL4. The tenth interlayer insulating film INS10 may be formed of a silicon oxide (SiOx)-based inorganic film, but the embodiments of the present disclosure are not limited thereto.

Each of the tenth vias VA10 may penetrate through the tenth interlayer insulating film INS10 to be connected to the exposed ninth metal layer ML9. The tenth vias VA10 may be made of copper (Cu), aluminum (Al), tungsten (W), molybdenum (Mo), chromium (Cr), gold (Au), titanium (Ti), nickel (Ni), neodymium (Nd), or an alloy thereof. Due to the step layer STPL, the thickness of the tenth via VA10 in the first sub-pixel SP1 may be smaller than the thickness of the tenth via VA10 in each of the second sub-pixel SP2 and the third sub-pixel SP3.

The emission material layer EML may be disposed on the emission material backplane EBP. The emission material layer EML may include light-emitting elements LE each including a first electrode AND, an intermediate layer IL, a second electrode CAT, and a pixel-defining film PDL.

The first electrode AND of each of the light-emitting elements LE may be disposed on the tenth interlayer insulating film INS10 and may be connected to the tenth via VA10. The first electrode AND of each of the light-emitting elements LE may be connected to the drain region DA or the source region SA of the pixel transistor PTR through the tenth via VA10, the first to fourth reflective electrodes RL1 to RL4, the first to ninth vias VA1 to VA9, the first to eighth metal layers ML1 to ML8 and the contact terminals CTE. The first electrode AND of each of the light-emitting elements LE may be made of copper (Cu), aluminum (Al), tungsten (W), molybdenum (Mo), chromium (Cr), gold (Au), titanium (Ti), nickel (Ni), neodymium (Nd), or an alloy thereof. For example, the first electrode AND of each of the light-emitting elements LE may be titanium nitride (TiN).

The pixel-defining film PDL may be disposed partially on the first electrode AND of each of the light-emitting elements LE. The pixel-defining film PDL may cover the edge of the first electrode AND of each of the light-emitting elements LE. The pixel-defining film PDL serves to partition the first emission areas EA1, the second emission areas EA2 and the third emission areas EA3.

A first emission area EA1 may be defined as an area in the first sub-pixel SP1 where the first electrode AND, the intermediate layer IL and the second electrode CAT are sequentially stacked on one another to emit light. A second emission area EA2 may be defined as an area in the second sub-pixel SP2 where the first electrode AND, the intermediate layer IL, and the second electrode CAT are sequentially stacked on one another to emit light. A third emission area EA3 may be defined as an area in the third sub-pixel SP3 where the first electrode AND, the intermediate layer IL, and the second electrode CAT are sequentially stacked on one another to emit light.

The pixel-defining film PDL may include first to third pixel-defining films PDL1, PDL2, and PDL3. The first pixel-defining film PDL1 may be disposed on the edge of the first electrode AND of each of the light-emitting elements LE, the second pixel-defining film PDL2 may be disposed on the first pixel-defining film PDL1, and the third pixel-defining film PDL3 may be disposed on the second pixel-defining film PDL2. The first pixel-defining film PDL1, the second pixel-defining film PDL2 and the third pixel-defining film PDL3 may be formed of a silicon oxide (SiOx)-based inorganic film, but the embodiments of the present disclosure are not limited thereto.

The intermediate layer IL may include a first intermediate layer IL1, a second intermediate layer IL2, and a third intermediate layer IL3.

The intermediate layer IL may have a tandem structure including a plurality of intermediate layers IL1, IL2, and IL3 that emit different lights. For example, the intermediate layer IL may include the first intermediate layer IL1 that emits light of the first color, the second intermediate layer IL2 that emits light of the third color, and the third intermediate layer IL3 that emits light of the second color. The first intermediate layer IL1, the second intermediate layer IL2, and the third intermediate layer IL3 may be sequentially stacked on one another.

The first intermediate layer IL1 may have a structure in which a first hole transport layer, a first organic emissive layer that emits light of the first color, and a first electron transport layer are sequentially stacked on one another. The second intermediate layer IL2 may have a structure in which a second hole transport layer, a second organic emissive layer that emits light of the second color, and a second electron transport layer are sequentially stacked on one another. The third intermediate layer IL3 may have a structure in which a third hole transport layer, a third organic emissive layer that emits light of the third colora, and a third electron transport layer are sequentially stacked on one another.

The number of intermediate layers IL1, IL2, and IL3 emitting different lights is not limited to that shown in FIG. 10. For example, the intermediate layer IL may include two intermediate layers. In such examples, one of the two intermediate layers is substantially identical to the first intermediate layer IL1, and the other one may include a second hole transport layer, a second organic emissive layer, a third organic emissive layer, and a second electron transport layer. In such examples, a charge generation layer may be disposed between the two intermediate layers to supply electrons to one intermediate layer and to supply charges to the other intermediate layer.

In addition, although the first to third intermediate layers IL1, IL2, and IL3 are all disposed in the first emission area EA1, the second emission area EA2 and the third emission area EA3 in FIG. 10, the embodiments of the present disclosure are not limited thereto. For example, the first intermediate layer IL1 may be disposed in the first emission area EA1 but not in the second emission area EA2 and the third emission area EA3. In addition, the second intermediate layer IL2 may be disposed in the second emission area EA2 but not in the first emission area EA1 and the third emission area EA3. In addition, the third intermediate layer IL3 may be disposed in the third emission area EA3 but not in the first emission area EA1 and the second emission area EA2. In such examples, the first to third color filters CF1, CF2, and CF3 of the optical layer OPL may be eliminated.

The second electrode CAT may be disposed on the third intermediate layer IL3. The second electrode CAT may be disposed on the third intermediate layer IL3 in each of a plurality of trenches TRC. The second electrode CAT may be formed of a transparent conductive material (TCP) such as ITO and IZO that can transmit light, or a semi-transmissive conductive material such as magnesium (Mg), silver (Ag), an alloy of magnesium (Mg) and silver (Ag), and/or the like. When the second electrode CAT is formed of a semi-transmissive conductive material, the light extraction efficiency can be increased by using microcavities in each of the first to third sub-pixels SP1, SP2, and SP3.

The encapsulation layer TFE may be disposed on the emission material layer EML. The encapsulation layer TFE may include one or more inorganic films TFE1 and TFE2 to prevent or substantially reduce permeation of oxygen or moisture into the emission material layer EML. In addition, the encapsulation layer ENC may include at least one organic film to protect the emission material layer EML from particles such as dust or the like. For example, the encapsulation layer ENC may include a first inorganic encapsulation film TFE1, an organic encapsulation film TFE2, and a second inorganic encapsulation film TFE3.

The first inorganic encapsulation film TFE1 may be disposed on the second electrode CAT, the organic encapsulation film TFE2 may be disposed on the first inorganic encapsulation film TFE1, and the second inorganic encapsulation film TFE3 may be disposed on the organic encapsulation film TFE2. The first inorganic encapsulation film TFE1 and the second inorganic encapsulation film TFE3 may be made up of multiple layers in which one or more inorganic layers of a silicon nitride layer (SiNx), a silicon oxynitride layer (SiON), a silicon oxide layer (SiOx), a titanium oxide layer (TiOx), and an aluminum oxide layer (AlOx) are alternately stacked on one another. The organic encapsulation film TFE2 may be a monomer. In some examples, the organic encapsulation film TFE2 may be an organic film such as an acryl resin, an epoxy resin, a phenolic resin, a polyamide resin, a polyimide resin, or the like.

An adhesive layer ADL may adhere the encapsulation layer TFE to the optical layer OPL. The adhesive layer ADL may be a double-sided adhesive member. In addition, the adhesive layer ADL may be a transparent adhesive member such as a transparent adhesive and a transparent adhesive resin.

The optical layer OPL includes a plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may be disposed on the adhesive layer ADL.

The first color filter CF1 may be in line with the first emission area EA1 of the first sub-pixel SP1. The first color filter CF1 may transmit light of the first color, for example, light in the blue wavelength range. The blue wavelength range may be about 370 nm to about 460 nm. Therefore, the first color filter CF1 may transmit light of the first color among the lights emitted from the first emission area EA1.

The second color filter CF2 may be in line with the second emission area EA2 of the second sub-pixel SP2. The second color filter CF2 may transmit light of the second color, for example, light in the green wavelength range. The green wavelength range may be about 480 nm to about 560 nm. Therefore, the second color filter CF2 may transmit light of the second color among the lights emitted from the second emission area EA2.

The third color filter CF3 may be in line with the third emission area EA3 of the third sub-pixel SP3. The third color filter CF3 may transmit light of the third color, for example, light in the red wavelength range. The blue wavelength range may be about 600 nm to about 750 nm. Therefore, the third color filter CF3 may transmit light of the third color among the lights emitted from the third emission area EA3.

The lenses LNS may be disposed on the first color filter CF1, the second color filter CF2 and the third color filter CF3, respectively. Each of the lenses LNS may be a structure for increasing the ratio of light directed to the front side of the display device 10. Each of the lenses LNS may have a cross-sectional shape that is convex upward.

The filling layer FIL may be disposed on a plurality of lenses LNS. The filling layer FIL may have a set or predetermined refractive index so that light travels in the third direction DR3 at the interface between the plurality of lenses LNS and the filling layer FIL. In addition, the filling layer FIL may be a planarization layer. The filling layer FIL may be an organic film such as an acryl resin, an epoxy resin, a phenolic resin, a polyamide resin, and a polyimide resin.

The cover layer CVL may be disposed on the filling layer FIL. The cover layer CVL may be a glass substrate or a polymer resin such as a resin. If the cover layer CVL is a glass substrate, it may be attached to the filling layer FIL. In such examples, the filling layer FIL may adhere the cover layer CVL. If the cover layer CVL is a glass substrate, it may work as an encapsulation substrate. If the cover layer CVL is a polymer resin such as a resin or the like, it may be applied directly on the filling layer FIL.

The polarizer may be disposed on a surface of the cover layer CVL. The polarizer may be a structure for preventing or substantially reducing deterioration of visibility due to reflection of external light. The polarizer may include a linear polarizer and a retardation film. For example, the retardation film may be a N/4 plate (quarter-wave plate), but the embodiments of the present disclosure are not limited thereto. If visibility is sufficiently improved by the first to third color filters CF1, CF2, and CF3 regardless of reflection of external light, the polarizer may be eliminated.

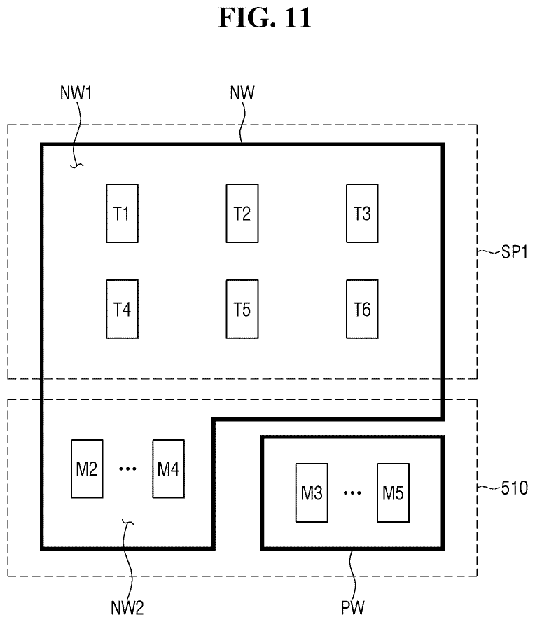

FIG. 11 is a cross-sectional view showing a layout of a first sub-pixel according to some embodiments of the present disclosure.

Referring to FIG. 11, a first well area NW doped with first-type impurities and a second well area PW doped with second-type impurities are located in a display area DAA of a display panel 410.

In the first well area NW, a plurality of pixel transistors (e.g., the transistors T1 to T8 in FIG. 8) included in a pixel driver circuit PC and a first transistor group (e.g., M1, M2, M4, M7 and M9 in FIG. 9) of a scan driver 510 are disposed. For example, the first well area NW includes a first sub-area NW1 where a plurality of pixel transistors (e.g., the transistors T1 to T8 in FIG. 8) included in the pixel driver circuit are disposed, and a second sub-area NW2 where the first transistor group (e.g., the transistors M1, M2, M4, M7 and M9 in FIG. 9) of the scan driver 510 is disposed.

A second transistor group (e.g., the transistors M3, M5, M6, M8 and M10 in FIG. 9) of the scan driver 510 is disposed in the second well area PW. The second well area PW may be arranged parallel to the second sub-area of the first well area NW.

The pixel transistors (e.g., the transistors T1 to T8 in FIG. 8) disposed in the first well area NW include p-type MOSFETs, as described above with reference to FIG. 8.

The first transistor group (e.g., the transistors M1, M2, M4, M7 and M9 in FIG. 9) of the scan driver 510 includes p-type MOSFETs, and the second transistor group (e.g., the transistors M3, M5, M6, M8 and M10 in FIG. 9) of the scan driver 510 includes n-type MOSFETs. For example, the p-type MOSFETs such as the second scan transistor M2 may be disposed in the second sub-area NW2 of the first well area NW. In addition, the n-type MOSFETs such as the third scan transistor M3 may be disposed in the second well area PW.

The first-type impurities are n-type impurities, and the second-type impurities are p-type impurities.

In some embodiments, the first well area NW may have an L-shape and the second well area PW may be located in a space defined by the two extensions of the L-shaped first well area NW.

According to some embodiments of the present disclosure, one first well area NW and one second well area PW may be disposed adjacent to each other to form one twin-well area, and the twin-well area may be arranged in a matrix in the display area DAA. That is to say, one first well area NW and one second well region PW may be disposed adjacent to each other and arranged with regularity. In other words, a plurality of twin well areas comprising the twin well area is arranged in the form of a repeating matrix pattern in the display area.

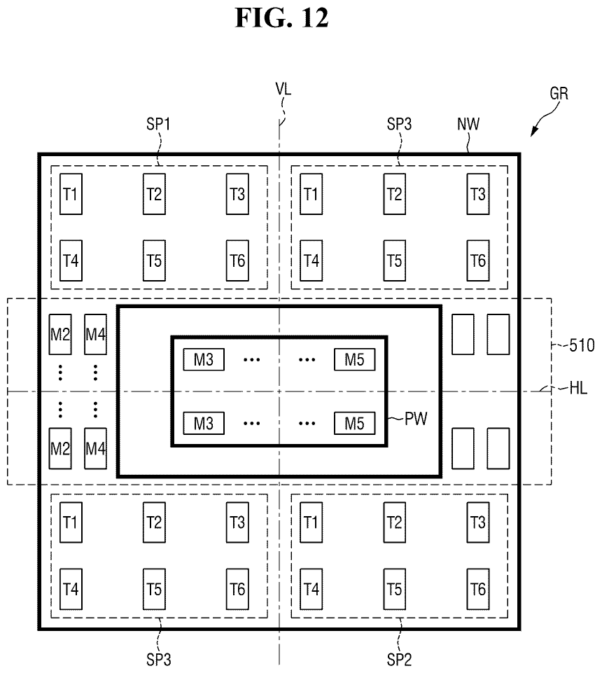

FIG. 12 is a view showing a layout of a pixel group according to some embodiments of the present disclosure.

Referring to FIG. 12, four sub-pixels SP1, SP2, and SP3 arranged in a 2×2 matrix form one pixel group GR, where ‘x’ denotes the multiplication sign. For example, a first sub-pixel SP1 may be disposed in the first row and the first column of the 2×2 matrix, one third sub-pixel SP3 may be disposed in the first row and second column of the 2×2 matrix, another third sub-pixel SP3 may be disposed in the second row and first column of the 2×2 matrix, and a second sub-pixel SP2 may be disposed in the second row and the second column of the 2×2 matrix. That is, in the of the 2×2 matrix, the first and second sub-pixel SP1 and SP2 may be diagonally across from one another, while the two third sub-pixel SP3 may be diagonally across from one another. However, the layout of the pixel group GR shown in FIG. 12 is merely an example, and the present disclosure is not limited thereto.

As such, one first well area NW and one second well area PW correspond to (e.g., are located in) the four sub-pixels SP1, SP2, and SP3 that are arranged in a 2-by-2 matrix. In each pixel group, one first well area NW may be arranged to surround one second well area PW.

In FIG. 12, imaginary lines VL and HL divide the four sub-pixels SP1, SP2, and SP3 arranged in the 2-by-2 matrix.

According to the embodiments of FIG. 12, the first well area NW is doped with n-type impurities and the second well area PW is doped with p-type impurities. It should be understood, however, that the present disclosure is not limited thereto. For example, the pixel transistors include n-type MOSFETs. In such examples, the first transistor group includes n-type MOSFETs, and the second transistor group includes p-type MOSFETs. In addition, the first-type impurities are p-type impurities, and the second-type impurities are n-type impurities.

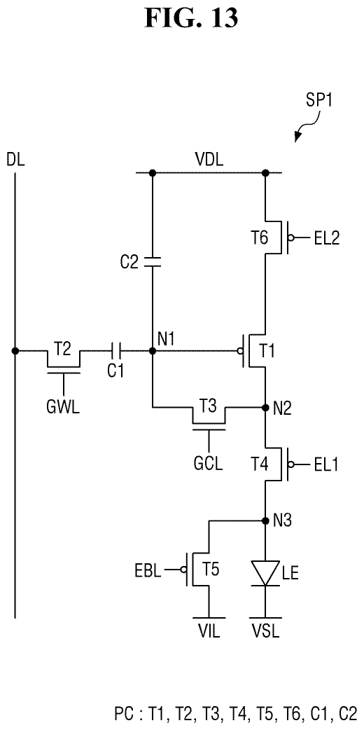

FIG. 13 is an equivalent circuit diagram of a first sub-pixel according to some embodiments of the present disclosure. FIG. 14 is a view showing a layout of a pixel group according to some embodiments of the present disclosure.

The embodiments of FIG. 13 is different from the embodiments of FIG. 8 in that a second transistor T2 and a third transistor T3 are n-type MOSFETs. For example, referring to FIG. 13, a sub-pixel according to some embodiments includes a plurality of pixel transistors T1 to T6. Some of the pixel transistors T1 to T6 may be n-type MOSFETs while the other transistors may be p-type MOSFETs. The equivalent circuit diagram shown in FIG. 13 is merely an example, and the present disclosure is not limited thereto.

Referring to FIGS. 13 and 14, four sub-pixels SP1, SP2, and SP3 arranged in a 2-by-2 matrix form a pixel group GR. For example, a first sub-pixel SP1 may be disposed in the first row and the first column, third sub-pixels SP3 may be disposed in the first row and second column and in the second row and first column, and a second sub-pixel SP2 may be disposed in the second row and the second column. The layout of the pixel group GR shown in FIG. 12 is merely an example, and the present disclosure is not limited thereto.

As such, referring to FIG. 14, a pair of first well areas NW and one second well area PW correspond to (e.g., are located in) the four sub-pixels SP1, SP2, and SP3 that are arranged in a 2-by-2 matrix. For example, in the of the 2×2 matrix, the first and second sub-pixel SP1 and SP2 may be diagonally across from one another, while the two third sub-pixel SP3 may be diagonally across from one another. The one second well area PW is disposed between the pair of first well areas NW.

In some embodiments, each first well area NW of the pair of first well areas NW may be U-shaped and facing inward toward a center of the 2-by-2 matrix, and the second well area PW may have a cross-shape and be located in the space defined by the inward facing U-shaped first well areas NW.

In FIG. 14, imaginary lines VL and HL divide the four sub-pixels arranged in the 2-by-2 matrix.

According to the embodiments of FIG. 14, the first well area NW is doped with n-type impurities and the second well area PW is doped with p-type impurities. It should be understood, however, that the present disclosure is not limited thereto. For example, the pixel transistors include n-type MOSFETs. In such examples, the first transistor group includes n-type MOSFETs, and the second transistor group includes p-type MOSFETs. In addition, the first-type impurities are p-type impurities, and the second-type impurities are n-type impurities.

Although the scan transistors of the scan driver 510 share the well areas with the pixel transistors in the following description, the plurality of light-emitting transistors of the emission driver 520 may also share the well areas with the pixel transistors. For example, a first well area NW doped with first-type impurities and a second well area PW doped with second-type impurities are located in the CMOS layer in the display area of the display panel, a plurality of pixel transistors T1 to T6 included in the pixel driving circuit PC and a first transistor group of the emission driver 520 are disposed in the first well area NW, and a second transistor group of the emission driver 520 is disposed in the second well area PW. The first transistor group includes p-type MOSFETs, and the second transistor group includes n-type MOSFETs.

In the display device and the mobile electronic device including the same according to the embodiments, the area of the display screen can be expanded by reducing the non-display area.

According to the display device and the mobile electronic device including the same according to embodiments, the fabrication costs can be reduced by reducing the size of each cell (e.g., net die) in a wafer that produces semiconductor substrates.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art. Further, if the term “substantially” is used in combination with a feature that could be expressed using a numeric value, the term “substantially” denotes a range of +/−5% of the value centered on the value. Furthermore, a specific quantity or range recited in this written description or the claims may also encompass the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

When one or more embodiments may be implemented differently, a specific process order may be performed differently from the described order. For example, (i) the disclosed operations of a process are merely examples, and may involve various additional operations not explicitly covered, and (ii) the temporal order of the operations may be varied.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification.

The display device and/or any other relevant devices or components according to embodiments of the present invention described herein may be implemented utilizing any suitable hardware, firmware (e.g., an application-specific integrated circuit), software, or a suitable combination of software, firmware, and hardware. For example, the various components of the display device may be formed on one integrated circuit (IC) chip or on separate IC chips. Further, the various components of the display device may be implemented on a flexible printed circuit film, a tape carrier package (TCP), a printed circuit board (PCB), or formed on a same substrate. Further, the various components of the display device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the exemplary embodiments of the present invention

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and equivalents thereof.

What is claimed is:

1. A display device comprising:
a pixel driver circuit comprising a plurality of pixel transistors;
a scan driver comprising a first transistor group and a second transistor group; and
a display panel comprising a semiconductor substrate, a complementary metal oxide semiconductor (CMOS) layer on the semiconductor substrate, and an emission material layer on the CMOS layer,
wherein the CMOS layer comprises a first well area doped with first-type impurities and a second well area doped with second-type impurities, the first and second well areas being in a display area of the display panel, and
wherein the plurality of pixel transistors and the first transistor group are in the first well area, and the second transistor group is in the second well area.

2. The display device of claim 1, wherein the plurality of pixel transistors comprises p-type MOSFETs.

3. The display device of claim 2, wherein the first transistor group comprises p-type MOSFETs, and the second transistor group comprises n-type MOSFETs.

4. The display device of claim 3, wherein the first-type impurities are n-type impurities, and
wherein the second-type impurities are p-type impurities.

5. The display device of claim 1, wherein the plurality of pixel transistors comprises n-type MOSFETs.

6. The display device of claim 5, wherein the first transistor group comprises n-type MOSFETs, and the second transistor group comprises p-type MOSFETs.

7. The display device of claim 6, wherein the first-type impurities are p-type impurities, and
wherein the second-type impurities are n-type impurities.

8. The display device of claim 1, wherein the first well area and the second well area are adjacent to each other to form one twin-well area, and
wherein a plurality of twin well areas comprising the twin well area is arranged in a matrix pattern in the display area.

9. The display device of claim 1, wherein the first well area and the second well area correspond to four sub-pixels of the display panel that are arranged in a 2×2 matrix, and
wherein the first well area surrounds the second well area.

10. The display device of claim 1, wherein the first well area comprises a pair of first well areas, the pair of first well areas and the second well area correspond to four sub-pixels of the display panel that are arranged in a 2×2 matrix, and
wherein the second well area is located between the pair of first well areas.

11. A mobile electronic device comprising:
a display panel comprising a semiconductor substrate, a complementary metal oxide semiconductor (CMOS) layer on the semiconductor substrate, and an emission material layer on the CMOS layer,
wherein the CMOS layer comprises a first well area doped with first-type impurities and a second well area doped with second-type impurities, the first and second well areas being in a display area of the display panel, and
wherein a plurality of pixel transistors of a pixel driver circuit and a first transistor group of a scan driver are in the first well area, and a second transistor group of the scan driver is in the second well area.

12. The mobile electronic device of claim 11, wherein the plurality of pixel transistors comprises p-type MOSFETs.

13. The mobile electronic device of claim 12, wherein the first transistor group comprises p-type MOSFETs, and the second transistor group comprises n-type MOSFETs.

14. The mobile electronic device of claim 13, wherein the first-type impurities are n-type impurities, and
wherein the second-type impurities are p-type impurities.

15. The mobile electronic device of claim 11, wherein the plurality of pixel transistors comprises n-type MOSFETs.

16. The mobile electronic device of claim 15, wherein the first transistor group comprises n-type MOSFETs, and the second transistor group comprises p-type MOSFETs.

17. The mobile electronic device of claim 16, wherein the first-type impurities are p-type impurities, and
wherein the second-type impurities are n-type impurities.

18. The mobile electronic device of claim 11, wherein the first well area and the second well area are adjacent to each other to form one twin-well area, and
wherein a plurality of twin well areas comprising the twin well area is arranged in a matrix pattern in the display area.

19. The mobile electronic device of claim 11, wherein the first well area and the second well area correspond to four sub-pixels of the display panel that are arranged in a 2×2 matrix, and
wherein the first well area surrounds the second well area.

20. The mobile electronic device of claim 11, wherein the first well area comprises a pair of first well areas, the pair of first well areas and the second well area correspond to four sub-pixels that are arranged in a 2×2 matrix, and
wherein the second well area is located between the pair of first well areas.
